(19) United States
(12) Patent Application Publication
(10) Pub. No.: US 2010/0237432 A1
(43) Pub. Date: Sep. 23, 2010

(54) SEMICONDUCTOR DEVICE AND METHOD FOR FABRICATING THE SAME

(75) Inventors: Shinji TAKEOKA, Toyama (JP); Takashi NAKABAYASHI, Osaka (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/793,613

(22) Filed: Jun. 3, 2010

Related U.S. Application Data
(63) Continuation of application No. PCT/JP2009/005216, filed on Oct. 7, 2009.

(30) Foreign Application Priority Data
Feb. 23, 2009 (JP) 2009-039827

(51) Int. Cl. H01L 27/092; H01L 21/762

(52) U.S. Cl. 257/369; 438/424; 257/E21.546; 257/E27.062

(57) ABSTRACT

A semiconductor device includes a MIS transistor formed in a FET formation region of a semiconductor substrate, a silicon dioxide film formed in a trench provided in the semiconductor substrate to define the FET formation region, a gate insulating film formed over the FET formation region and the silicon dioxide film, and a gate electrode formed on the gate insulating film. The portion of the gate insulating film formed between the portion of the gate electrode located in the trench and the side surface of the semiconductor substrate contains aluminum, while the portion of the gate insulating film formed between the gate electrode and the upper surface of the semiconductor substrate does not contain aluminum.

### CROSS-REFERENCE TO RELATED APPLICATION

This is a continuation of PCT International Application PCT/JP2009/005216 filed on Oct. 7, 2009, which claims priority to Japanese Patent Application No. 2009-039827 filed on Feb. 23, 2009. The disclosures of these applications including the specifications, the drawings, and the claims are hereby incorporated by reference in its entirety.

### BACKGROUND

The technology disclosed in the present disclosure relates to a semiconductor device and a method for fabricating the same. More particularly, the technology disclosed in the present disclosure relates to a transistor having a structure capable of inhibiting a reduction in the threshold voltage of a parasitic transistor formed in the vicinity of the edge of a shallow trench isolation (STI) and a method for fabricating the same.

As design rules for semiconductor devices have decreased, the degrees of integration of circuits have exponentially improved. For example, even a hundred of millions or more of field effect transistors (hereinafter referred to as FETs) can be mounted on a single chip. To achieve high integration of transistors, not only a reduction in gate length, but also a reduction in gate width is required. In the 45 nm generation using leading-edge semiconductor processes, miniaturized transistors having gate lengths of about 40 nm and gate widths of about 100 nm have been implemented. As a result, in the structure of transistors having narrow gate widths, the influence of a parasitic transistor has become non-negligible.

FIGS. 11A-11D and FIGS. 12A-12C show a method for fabricating a conventional semiconductor device in which parasitic transistors are formed in the order of process steps.

First, as shown in FIG. 11A, a silicon dioxide film 501 having a thickness of 10 nm is formed on a silicon substrate 500. Then, a silicon nitride film 502 having a thickness of 70 nm is formed on the silicon dioxide film 501. Subsequent, a resist film is formed on the silicon nitride film 502, and then formed into a resist pattern 503 having an opening exposing the silicon nitride film 502.

Next, as shown in FIG. 11B, the silicon nitride film 502, the silicon dioxide film 501, and the silicon substrate 500 are etched using the resist pattern 503 as a mask. As a result, a trench 504 having a depth of 300 nm is formed in the silicon substrate 500. Subsequently, by oxidizing the silicon substrate 500, an underlying insulating film 505 having a thickness of 5 nm is formed on the sidewall portions and bottom portion of the trench 504.

Next, as shown in FIG. 11C, a silicon dioxide film 506 having a thickness of 500 nm is formed over the entire surface of the silicon substrate 500 using, e.g., a plasma chemical vapor deposition (CVD) process or a thermal CVD process so as to fill the inside of the trench 504. In this manner, electrical isolation using the silicon dioxide film 506 is achieved.

Next, as shown in FIG. 11D, the portion of the silicon dioxide film 506 located over the silicon nitride film 502 is removed by polishing to provide a planarized surface.

Next, as shown in FIG. 12A, the silicon nitride film 502 on the silicon dioxide film 501 is removed by etching using a chemical solution of, e.g., a phosphoric acid or the like. Subsequently, a resist pattern (not shown) having an opening over a desired region is formed. Then, using the resist pattern as a mask, impurity implantation 507 is performed to the silicon substrate 500. As an impurity used for the impurity implantation 507, a P-type impurity such as, e.g., boron or indium is used when an NFET is to be formed, and an N-type impurity such as, e.g., arsenic or phosphorus is used when a PFET is to be formed, thereby forming a well and adjusting the threshold voltage of a channel region.

Next, as shown in FIG. 12B, annealing for activating the impurity implanted in the silicon substrate 500 is performed. Subsequently, the silicon dioxide film 501 is removed by etching using a chemical solution of, e.g., a hydrofluoric acid or the like. At this time, the upper portions of the respective portions of the underlying insulating film 505 located at the sidewall portions of the trench 504 and a part of the silicon dioxide film 506 buried in the trench 504 are also removed due to the chemical solution that has reached there. As a result, divots 508 are formed at the upper portions of the sidewall portions of the trench 504 and between the silicon substrate 500 and the silicon dioxide film 506.

Next, as shown in FIG. 12C, a gate insulating film 509 made of, e.g., a silicon dioxide film having a thickness of, e.g., 2 nm is formed on the exposed upper portions of silicon substrate 500 and on the upper portions of the sidewall portions of the trench 504 that have been exposed as a result of the formation of the divots 508 by a thermal oxidation process. Subsequently, a gate electrode 510 made of a polysilicon film having a thickness of, e.g., 100 nm is formed on the gate insulating film 509.

Here, FIG. 13 is an enlarged cross-sectional view of the region 12A in FIG. 12C.

As shown in FIG. 13, the silicon dioxide film 506 and the underlying insulating film 505 are each formed to be recessed in the depth direction of the silicon substrate 500 along the sidewalls of the trench 504, as compared to those in FIG. 12A (i.e., the divots 508 (see FIG. 12B) are formed). In the regions where the divots 508 are formed, the gate insulating film 509 is formed on the upper portions of the sidewall portions of the trench 504 that have been exposed as a result of the recession, and the gate electrode 510 is further formed on the gate insulating film 509. As a result, the upper portion of each of the sidewall portions of the trench 504 in the vicinities of the edges of the silicon dioxide film 506 has a structure in which the silicon substrate 500, the gate insulating film 509, and the gate electrode 510 are stacked so that parasitic transistors are formed.

The parasitic transistors thus formed are assumed to be present in parasitic transistor formation regions A in the vicinities of the edges of a STI defining element formation regions in each of which a FET including a source region S, a drain region D, and a gate electrode G (having a gate length L and a gate width W) is formed, as shown in a plan view of FIG. 14 (see, e.g., Japanese Laid-Open Patent Publication No. 2001-135720).

### SUMMARY

As described above, in the structure of a transistor having a narrow gate width, the influence of a parasitic transistor has become unignorable. This is because, due to factors such as an electric field concentration effect (the concentration of an electric field to an upper corner portion of a silicon substrate due to a gate bias) and the effect of a substrate impurity reduction (a reduction in the concentration of an impurity implanted in the silicon substrate for the adjustment of a threshold voltage, which results from the absorption of the impurity in an insulating film in a trench caused by a thermal process needed during the activation of a well and during the formation of a gate insulating film), the threshold voltage of each of the parasitic transistors formed in the parasitic transistor formation regions A tends to be lower than the threshold voltage of a transistor at the center portion of a gate electrode, as shown by the Id-Vg (drain current versus gate voltage) characteristic curve of FIG. 15.

Since it is difficult to equalize the influence of the parasitic transistor given to the entire transistor including the transistor at the center portion, the Id-Vg characteristic of the entire transistor shown in FIG. 14 varies between the Id-Vg characteristic of each of the parasitic transistors and the Id-Vg characteristic of the transistor at the center portion which are shown in FIG. 15. As a result, variations occur in device characteristics during mass production.

To prevent this, as shown in FIG. 16, a method has been proposed which uses an underlying insulating film 600 made of, e.g., a silicon oxynitride film having a relatively large thickness as a material having a low etching rate to a hydrofluoric acid, and thereby reduces a reduction in the upper portion of the underlying insulating film 600 during the removal of the silicon dioxide film 501 (see, e.g., Japanese Laid-Open Patent Publication No. 2001-135720) and reduces the formation of the parasitic transistors. As a result, the formation of divots is inhibited, and the regions where parasitic transistors each having a low threshold voltage are formed can be reduced. However, to keep up with miniaturization in which the width of the STI region is reduced to, e.g., 50 nm, the thickness of the underlying insulating film at the sidewall portions of a trench also needs to be reduced to, e.g., 5 nm or less. In this case, the effect of inhibiting the formation of the divots is reduced so that variations occur in device characteristics. Moreover, in the case where an input/output circuit is mixedly mounted, the number of times wet etching is performed increases to result in a further reduction in the effect of inhibiting the formation of the divots and further variations in device characteristics.

In view of the foregoing, an object of the present disclosure is to provide a semiconductor device having a structure capable of inhibiting a reduction in the threshold voltage of a parasitic transistor, and a method for fabricating the same.

To attain the object, illustrative means according to the present disclosure will be shown below.

A semiconductor device includes: a first MIS transistor formed in a first element formation region of a semiconductor substrate; an isolation region formed in a trench provided in the semiconductor substrate to define the first element formation region; a first high-dielectric-constant gate insulating film formed over the first element formation region and the isolation region; and a first gate electrode formed on the first high-dielectric-constant gate insulating film, wherein a first portion of the first high-dielectric-constant gate insulating film formed between a portion of the first gate electrode located in the trench and a side surface of the first element formation region contains a first metal, and a second portion of the first high-dielectric-constant gate insulating film formed between the first gate electrode and an upper surface of the first element formation region does not contain the first metal.

In the semiconductor device described above, a lowermost surface of a region of the first gate electrode formed on the first portion of the first high-dielectric-constant gate insulating film is preferably at a position lower than a position of the upper surface of the first element formation region.

In the semiconductor device described above, at least a portion of the second portion of the first high-dielectric-constant gate insulating film spaced apart from the trench preferably does not contain the first metal.

In the semiconductor device described above, the isolation region may have: an isolation insulating film formed in the trench; a first underlying insulating film formed between the first element formation region and the isolation insulating film and at a sidewall portion of the trench; and a first protective film formed between the isolation insulating film and the first underlying insulating film, and containing the first metal.

In the semiconductor device described above, the first gate electrode may be formed on the side surface of the first element formation region with the first underlying insulating film, the first protective film, and the first portion of the first high-dielectric-constant gate insulating film interposed therebetween.

In the semiconductor device described above, the first underlying insulating film may be made of a silicon dioxide film or a silicon oxynitride film.

In the semiconductor device described above, when the first MIS transistor is an N-channel MIS transistor, the first protective film may be made of an aluminum film or an aluminum oxide film.

In the semiconductor device described above, when the first MIS transistor is an N-channel MIS transistor, the first metal may be aluminum.

In the semiconductor device described above, when the first MIS transistor is an N-channel MIS transistor, the second portion of the first high-dielectric-constant gate insulating film may contain any one selected from the group consisting of lanthanum, dysprosium, scandium, erbium, and strontium.

In the semiconductor device described above, when the first MIS transistor is a P-channel MIS transistor, the first protective film may be made of a film made of any one selected from the group consisting of lanthanum, dysprosium, scandium, erbium, and strontium or an oxide film of any one selected therefrom.

In the semiconductor device described above, when the first MIS transistor is a P-channel MIS transistor, the first metal may be lanthanum, dysprosium, scandium, erbium, or strontium.

In the semiconductor device described above, when the first MIS transistor is a P-channel MIS transistor, the second portion of the first high-dielectric-constant gate insulating film may contain aluminum.

In the semiconductor device described above, the first high-dielectric-constant gate insulating film may be made of a hafnium oxide film, a hafnium silicon oxide film, a hafnium silicon oxynitride film, a zirconium dioxide film, or a hafnium-zirconium oxide film.

In the semiconductor device described above, the first gate electrode has a film of at least one of titanium nitride, tantalum nitride, tantalum carbide, and tantalum carbonitride.

There may be a case where, in the semiconductor device described above, the isolation region defines the first element formation region, and a second element formation region of the semiconductor substrate where a second MIS transistor is formed, the semiconductor device further including: a second high-dielectric-constant gate insulating film formed over the second element formation region and the isolation region; and a second gate electrode formed on the second high-dielectric-constant gate insulating film, wherein a first portion of the second high-dielectric-constant gate insulating film formed between a portion of the second gate electrode located in the trench and a side surface of the second element formation region contains a second metal different from the first metal, and a second portion of the second high-dielectric-constant gate insulating film formed between the second gate electrode and an upper surface of the second element formation region does not contain the second metal.

In this case, the isolation region may have: an isolation insulating film formed in the trench; a first underlying insulating film formed between the first element formation region and the isolation insulating film and at a sidewall portion of the trench; a first protective film formed between the isolation insulating film and the first underlying insulating film, and containing the first metal; a second underlying insulating film formed between the second element formation region and the isolation insulating film and at a sidewall portion of the trench; and a second protective film formed between the isolation insulating film and the second underlying insulating film, and containing the second metal.

Further, when the first MIS transistor is an N-channel MIS transistor, and the second MIS transistor is a P-channel MIS transistor, the first protective film may be made of an aluminum film or an aluminum oxide film, and the second protective film may be made of a film made of any one selected from the group consisting of lanthanum, dysprosium, scandium, erbium, and strontium or an oxide film of any one selected therefrom.

Further, when the first MIS transistor is an N-channel MIS transistor, and the second MIS transistor is a P-channel MIS transistor, the first metal may be aluminum, and the second metal may be lanthanum, dysprosium, scandium, erbium, or strontium.

A method for fabricating a semiconductor device including a first MIS transistor formed in a first element formation region of a semiconductor substrate includes the steps of: (a) forming a trench defining the first element formation region in the semiconductor substrate, and then forming an isolation region in the trench; (b) forming a first high-dielectric-constant gate insulating film over the first element formation region and the isolation region; (c) forming a first gate electrode on the first high-dielectric-constant gate insulating film; and (d) introducing a first metal into a first portion of the first high-dielectric-constant gate insulating film formed between a portion of the first gate electrode located in the trench and a side surface of the first element formation region, wherein, in the step (d), the first metal is not introduced into a second portion of the first-high-dielectric-constant gate insulating film formed between the first gate electrode and an upper surface of the first element formation region.

In the method for fabricating the semiconductor device described above, the step (a) has the steps of: (a1) forming the trench in the semiconductor substrate; (a2) successively forming a first underlying insulating film and a first protective film containing the first metal at a sidewall portion of the trench in the first element formation region; and, (a3) after the step (a2), forming an isolation insulating film to fill the inside of the trench therewith, wherein the step (d) may include the step of introducing the first metal contained in the first protective film into the first high-dielectric-constant gate insulating film.

With the semiconductor device and the method for fabricating the same each described above, it is possible to inhibit a reduction in the threshold voltage of a parasitic transistor, and consequently reduce variations in transistors.

### BRIEF DESCRIPTION OF THE DRAWINGS

FIG. 1 is a plan view showing a structure of a semiconductor device according to a first illustrative example embodiment of the present disclosure.

FIGS. 2A-2D are principal-portion cross sections illustrating a method for fabricating the semiconductor device according to the first illustrative example embodiment in the order of process steps.

FIGS. 3A-3D are principal-portion cross sections illustrating the method for fabricating the semiconductor device according to the first illustrative example embodiment in the order of process steps.

FIG. 4 is a cross-sectional view showing the structure of the semiconductor device according to the first illustrative example embodiment, which is an enlarged cross-sectional view of the principal portion of FIG. 3D.

FIG. 5 is a plan view showing a structure of a semiconductor device according to a second illustrative example embodiment of the present disclosure.

FIGS. 6A-6D are principal-portion cross sections illustrating a method for fabricating the semiconductor device according to the second illustrative example embodiment in the order of process steps.

FIGS. 7A-7D are principal-portion cross sections illustrating the method for fabricating the semiconductor device according to the second illustrative example embodiment in the order of process steps.

FIGS. 8A-8C are principal-portion cross sections illustrating the method for fabricating the semiconductor device according to the second illustrative example embodiment in the order of process steps.

FIGS. 9A and 9B are principal-portion cross sections illustrating the method for fabricating the semiconductor device according to the second illustrative example embodiment in the order of process steps.

FIG. 10 is a cross-sectional view showing the structure of the semiconductor device according to the second illustrative example embodiment, which is an enlarged cross-sectional view of the principal portion of FIG. 9B.

FIGS. 11A-11D are principal-portion cross sections illustrating a method for fabricating a conventional semiconductor device in the order of process steps.

FIGS. 12A-12C are principal-portion cross sections illustrating the method for fabricating the conventional semiconductor device in the order of process steps.

FIG. 13 is a principal-portion cross section showing a structure of the conventional semiconductor device.

FIG. 14 is a plan view showing the regions where parasitic transistors are formed in the structure of the conventional semiconductor device.

FIG. 15 is an Id-Vg graph of each of the parasitic transistors and a transistor at a center portion in the conventional semiconductor device.

FIG. 16 is a principal-portion cross section showing a structure of a conventional semiconductor device.

### DETAILED DESCRIPTION

The following illustrative example embodiments are for clearly describing the technical idea of the present disclosure using drawings and a detailed description. Any person skilled in the art of the technical field concerned who has understood the preferred illustrative example embodiments of the present disclosure can modify or make an addition to the preferred illustrative example embodiments based on the technique disclosed in the present disclosure, and this would not depart from the technical idea and scope of the present disclosure.

### First Illustrative Example Embodiment

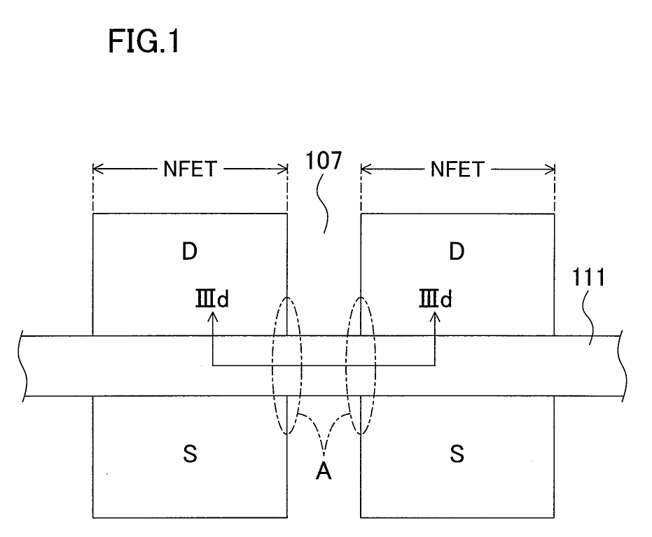

A semiconductor device and a method for fabricating the same according to a first illustrative example embodiment of the present disclosure will be described. Specifically, a semiconductor device and a method for fabricating the same will be described below which can mitigate, in a structure (see FIG. 1 described below) wherein N-channel metal-insulator-semiconductor (MIS) transistors (hereinafter referred to as N-type field effect transistors (NFETs)) are provided on a substrate to be adjacent to each other with a shallow trench isolation (STI) region interposed therebetween, a reduction in the threshold voltage of each of parasitic transistors formed in the vicinities of the edges of an STI region in the individual NFETs.

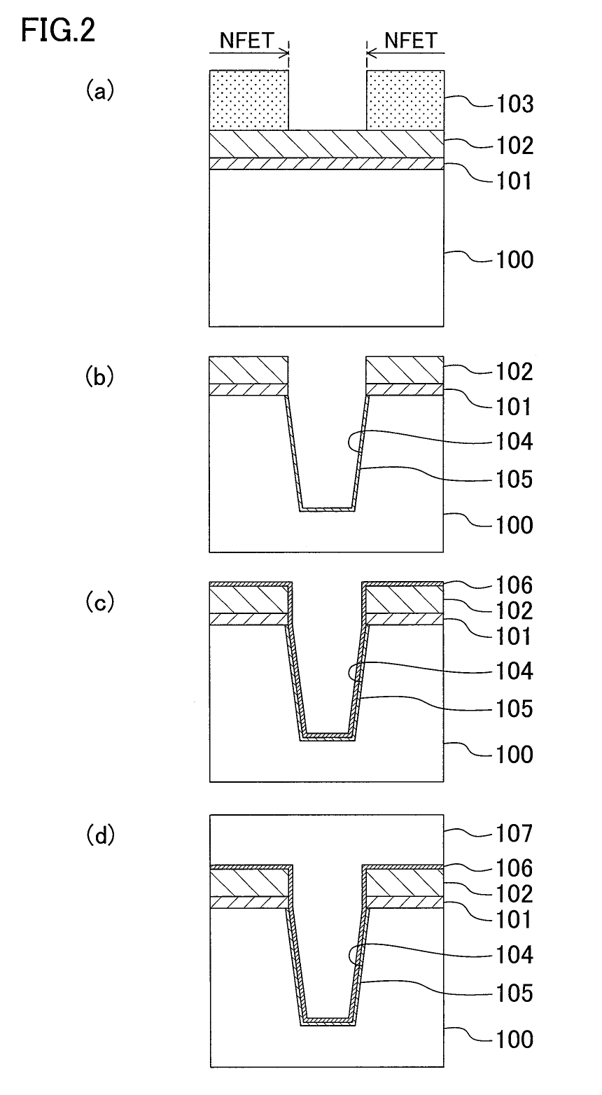

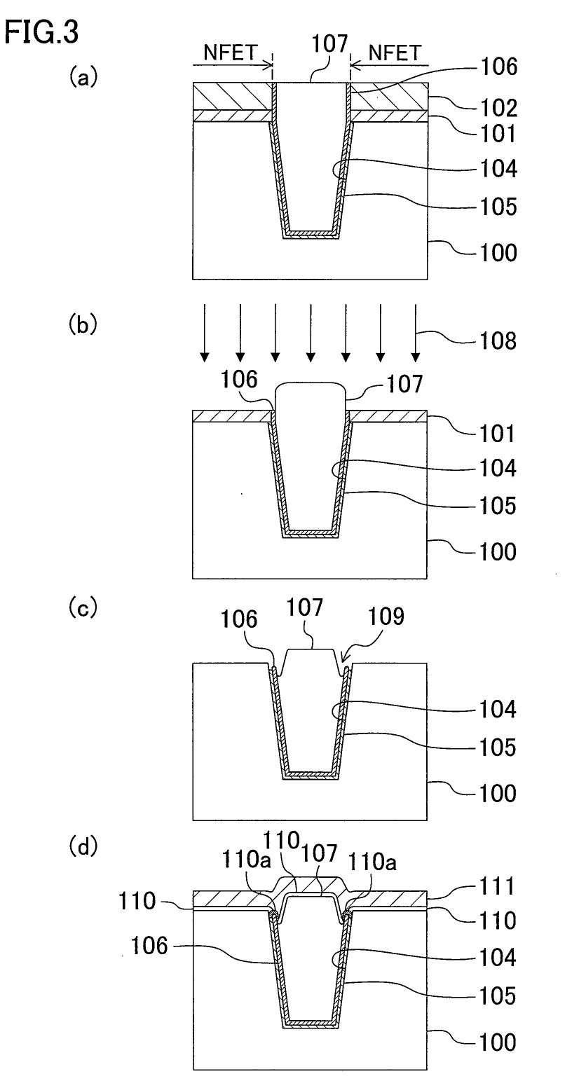

FIG. 1 shows a plan configuration of the semiconductor device according to the first illustrative example embodiment. FIGS. 2A-2D and 3A-3D are cross-sectional views illustrating the method for fabricating the semiconductor device according to the first illustrative example embodiment in the order of process steps, which specifically show cross sections each corresponding to the line IIId-IIId of FIG. 1 described above in the order of process steps. Note that, as shown in FIG. 1, parasitic transistors are assumed to be present in parasitic transistor formation regions A in the vicinities of the edges of a silicon dioxide film 107 serving as a STI (isolation insulating film) defining element formation regions in each of which an NFET including a source region S, a drain region D, and a gate electrode 111 is formed.

First, as shown in FIG. 2A, a silicon dioxide film 101 having a thickness of, e.g., 10 nm is formed on a semiconductor substrate (hereinafter referred to as the “substrate”) 100 made of, e.g., silicon. Then, a silicon nitride film 102 having a thickness of, e.g., 70 nm is formed on the silicon dioxide film 101. Subsequently, a resist film is deposited on the silicon nitride film 102, and then formed into a resist pattern 103 having an opening exposing the silicon nitride film 102 using photolithographic and etching techniques.

Then, as shown in FIG. 2B, the silicon nitride film 102, the silicon dioxide film 101, and the substrate 100 are etched using the resist pattern 103 as a mask. As a result, a trench 104 having a depth of 300 nm is formed in the substrate 100. Thereafter, the resist pattern 103 is removed. Subsequently, by oxidizing the substrate 100, an underlying insulating film 105 made of a silicon dioxide film having a thickness of, e.g., 2 nm is formed over the sidewall portions and bottom portion of the trench 104. Here, the description has been given to the case where the underlying insulating film 105 is a silicon dioxide film. However, the underlying insulating film 105 may also be made of, e.g., a silicon oxynitride film. Also, the thickness of the underlying insulating film 105 is not limited to 2 nm. The same effects as described above are obtainable as long as the thickness of the underlying insulating film 105 is in a range of about 0.5 to 15 nm.

Next, as shown in FIG. 2C, a protective film 106 made of an aluminum oxide film having a thickness of, e.g., 1 nm is deposited over the upper surface and side surfaces of the silicon nitride film 102, at the side surfaces of the silicon dioxide film 101, and on the underlying insulating film 105 using, e.g., an atomic layer deposition (ALD) process. Aluminum in the protective film 106 is introduced into a high-dielectric-constant gate insulating film (gate insulating film 110) made of a high-dielectric-constant material described later, and operates to increase the threshold voltage of the parasitic transistor in each of the NFETs. Here, as the protective film 106, a film containing a metal capable of increasing the threshold voltage of the parasitic transistor in the NFET, and having an etching rate lower than that of the isolation insulating film may be used appropriately. Instead of the aluminum oxide film, an aluminum film may also be used as the protective film 106. The description has been given to the case where the thickness of the protective film 106 is 1 nm, but it is not limited to the value. The thickness of the protective film 106 can be adjusted depending on a threshold voltage reduction in the parasitic transistor. That is, in the case where the threshold voltage reduction is assumed to decrease, the thickness of the protective film 106 may be reduced (to, e.g., 0.5 nm) appropriately. On the other hand, in the case where the threshold voltage reduction is assumed to increase, the thickness of the protective film 106 may be increased (to, e.g., 2 nm) appropriately.

Next, as shown in FIG. 2D, the silicon dioxide film 107 having a thickness of, e.g., 500 nm is formed over the entire surface of the substrate 100 so as to fill the inside of the trench 104 using a plasma chemical vapor deposition (CVD) process or a thermal CVD process. In this manner, electric isolation using the silicon dioxide film 107 serving as the isolation insulating film of the STI region is achieved.

Next, as shown in FIG. 3A, the portion of the silicon dioxide film 107 located over the silicon nitride film 102 and the portion of the protective film 106 located over the silicon nitride film 102 are removed by polishing to provide a planarized surface.

Next, as shown in FIG. 3B, the portion of the silicon nitride film 102 located over the silicon dioxide film 101 and the portion of the protective film 106 located over the silicon dioxide film 101 are removed by etching using a chemical solution of, e.g., a phosphoric acid or the like. Subsequently, a resist pattern (not shown) having an opening over a desired region is formed, and then impurity implantation 108 is performed to the substrate 100 using the resist pattern as a mask. Thereafter, the resist pattern is removed. Here, in the case of the first illustrative example embodiment, the NFETs are formed so that a P-type impurity such as, e.g., boron or indium is used as an impurity used for the impurity implantation 108 to form a well and adjust the threshold voltage of a channel region. Note that, in the case of forming PFETs, an N-type impurity such as, e.g., arsenic or phosphorus is used appropriately.

Next, as shown in FIG. 3C, annealing for activating the impurity implanted in the substrate 100 is performed. Subsequently, the silicon dioxide film 101 is removed by etching using a chemical solution of, e.g., a hydrofluoric acid or the like. At this time, the upper portions of the respective portions of the underlying insulating film 105 and the protective film 106 located at the sidewall portions of the trench 104 and a part of the silicon dioxide film 107 buried in the trench 104 are removed due to the chemical solution that has reached there. Note that the amount of the silicon dioxide film 107 removed here is larger than that of the protective film 106 removed. As a result, divots 109 are formed at the upper portions of the sidewall portions of the trench 104 and between the protective film 106 and the silicon dioxide film 107.

Next, as shown in FIG. 3D, by, e.g., an ALD process, the gate insulating film (high-dielectric-constant gate insulating film) 110 made of a hafnium oxide (HfO₂) film which is a high-dielectric-constant material having a thickness of, e.g., 2 nm is formed on the upper portion of the substrate 100, on the upper portions of the respective portions of the underlying insulating film 105 and the protective film 106 located at the sidewall portions of the trench 104, and on the silicon dioxide film 107. Subsequently, the gate electrode 111 made of a titanium nitride (TiN) film having a thickness of, e.g., 100 nm is formed on the gate insulating film 110. At this time, the lowermost bottom surfaces of the portions (portions located at the upper portions of the sidewall portions of the trench 104) of the gate electrode 111 buried in the divots 109 over the gate insulating film 110 are at positions (height positions) lower than the positions (height positions) of the upper surfaces of the element formation regions where the NFETs are to be formed.

Here, the description has been given to the case where the gate insulating film 110 is a HfO₂ film, and the gate electrode 111 is a TiN film. However, the gate insulating film 110 and the gate electrode 111 are not limited to these thicknesses and materials. For example, as the gate insulating film 110, there may also be used a high-dielectric-constant material such as the hafnium oxide (HfO₂) film mentioned above, a hafnium silicon oxide (HfSiO) film, a hafnium silicon oxynitride (HfSiON) film, a zirconium dioxide (ZrO₂) film, or a hafnium-zirconium oxide (HfZrO) film. As the gate electrode 111, there may also be used a single-layer film of any one of the titanium nitride (TiN) film mentioned above, a tantalum nitride (TaN) film, a tantalum carbide (TaC) film, a tantalum carbonitride (TaCN) film, and the like, a laminated film of any two or more thereof, or a laminated film of any one thereof and a polysilicon film formed thereon. Further, by introducing lanthanum (La), dysprosium (Dy), scandium (Sc), erbium (Er), or strontium (Sr) into the portion of the gate insulating film 110 located over the substrate 100, it is possible to inhibit an increase in the threshold voltage of each of the NFETs in the upper portion of the substrate 100 due to the gate insulating film 110 made of the high-dielectric-constant material mentioned above.

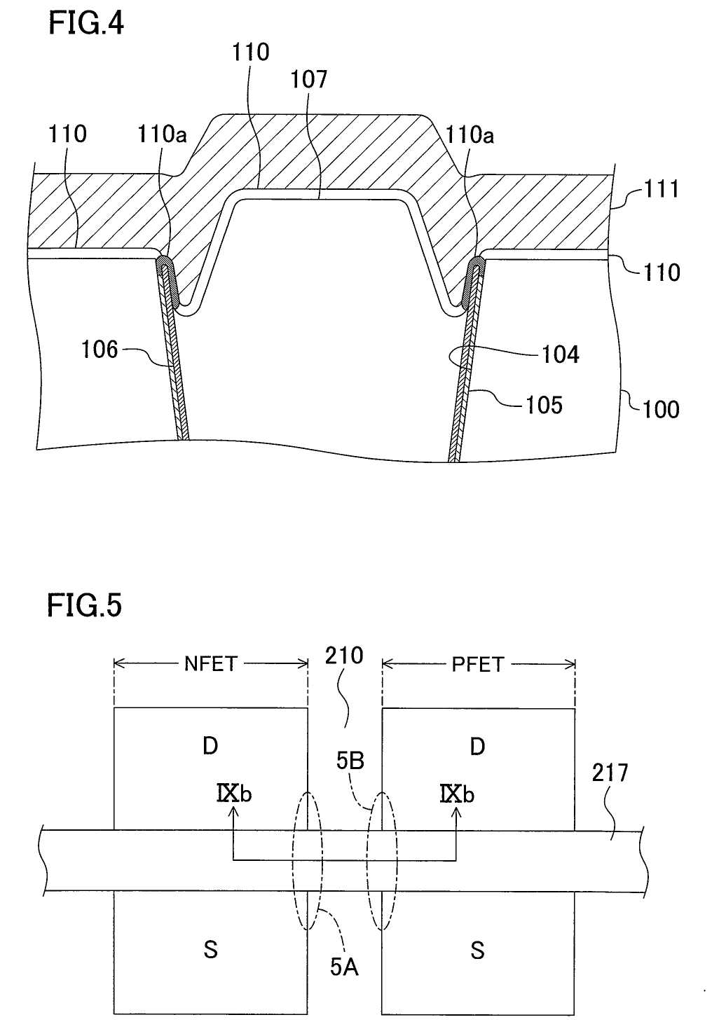

FIG. 4 is a cross-sectional view showing the structure of the semiconductor device according to the first illustrative example embodiment fabricated in the manner described above, which is an enlarged cross-sectional view of the principal portion of FIG. 3D described above.

As shown in FIG. 4, in the vicinities of the edges of the silicon dioxide film 107 serving as the isolation insulating film forming the STI region defining the NFET formation regions (element formation regions) of the substrate 100 (see FIG. 1), the protective film 106 made of, e.g., an aluminum oxide film is formed between the portions of the underlying insulating film 105 formed at the sidewall portions of the trench 104 and the gate insulating film 110. Aluminum-containing gate insulating films 110a for increasing the threshold voltage of the parasitic transistor in each of the NFETs are formed in the portions of the gate insulating film 110 located at the upper portions of the sidewall portions of the trench 104 in contact with the protective film 106. The aluminum-containing gate insulating films 110a are formed through the introduction of aluminum in the protective film 106 into the gate insulating film 110 by a thermal process after the formation of the gate insulating film 110. Accordingly, aluminum is not introduced into the portions of the gate insulating film 110 interposed between the gate electrode 111 and the upper surfaces of the NFET element formation regions, especially at least the portions thereof spaced apart from the trench 104. Since the aluminum-containing gate insulating films 110a are thus formed due to the presence of the protective film 106, even when the divots 109 are formed in the vicinities of the edges of the STI region, and parasitic transistors are formed, it is possible to inhibit a reduction in the threshold voltage of each of the parasitic transistors. In the case of the structure of the semiconductor device according to the first illustrative example embodiment, by providing the aluminum-containing gate insulating films 110a into which aluminum capable of increasing the threshold voltage has been introduced via the protective film 106, the threshold voltage of each of the parasitic transistors can be improved by about 200 mV. This allows a reduction in the characteristic variations of each of the transistors. In addition, as described above, the thickness of the underlying insulating film 105 may fall appropriately within a range of about 0.5 to 15 nm, and the thickness of the protective film 106 may fall appropriately within a range of about 0.5 to 2 nm. Therefore, even when the miniaturization of the transistors advances, the structure according to the first illustrative example embodiment is applicable thereto.

In the structure of the semiconductor device and the method for fabricating the same according to the first illustrative example embodiment described above, the structure is shown in which the protective film 106 is interposed between the underlying insulating film 105 and the aluminum-containing gate insulating films 110a in the vicinities of the edges of the STI region. However, the boundary of the protective film 106 need not be distinct. For example, even in a structure in which the underlying insulating film 105 and the aluminum-containing gate insulating films 110a are in contact with each other with an interface layer having a high aluminum concentration interposed therebetween, the same effects as described above are obtainable.

In the case of the structure of the semiconductor device and the method for fabricating the same according to the first illustrative example embodiment described above, the structure in which the NFETs are formed in the element formation regions defined by the STI region has been described as an example. However, even from a structure in which PFETs are formed instead of the NFETs, the same effects are obtainable. That is, as the protective film 106, a film containing a metal capable of increasing the threshold voltage of each of the parasitic transistors in the PFETs, and having an etching rate lower than that of the isolation insulating film may be used appropriately. For example, a film made of any one of lanthanum (La), dysprosium (Dy), scandium (Sc), erbium (Er), or strontium (Sr) or an oxide film of any one thereof is used. In this manner, it is possible to form a gate insulating film containing a metal capable of increasing the threshold voltage of each of the parasitic transistors in the PFETs, and therefore inhibit a reduction in the threshold voltage of the parasitic transistor. Also in this case, by introducing Al into the portion of the gate insulating film 110 located over the substrate 100, a threshold voltage increase due to the gate insulating film 110 made of the foregoing high-dielectric-constant material can be inhibited in the upper portion of the substrate 100. Note that, in the case of the structure in which PFETs are formed, an impurity implanted into the substrate 100 is an N-type impurity such as, e.g., arsenic or phosphorus.

In the case of forming the gate insulating film 110 by a CVD process, the gate insulating film 110 tends to be thinner in the divots 109 in the three-dimensional structure due to a reduced deposition speed. This causes concern about a reduction in the threshold voltage of the parasitic transistor due to the thinner gate insulating film 110. However, in the structure of the semiconductor device and the method for fabricating the same according to the first illustrative example embodiment described above, the protective film 106 is provided, and therefore a reduction in the threshold voltage of each of the parasitic transistors can be inhibited.

### Second Illustrative Example Embodiment

A semiconductor device and a method for fabricating the same according to a second illustrative example embodiment of the present disclosure will be described. Specifically, a description will be given below to a semiconductor device and a method for fabricating the same which can inhibit, in a structure (see FIG. 5 described below) wherein an N-channel metal-insulator-semiconductor (MIS) field effect transistor (hereinafter referred to as an N-type field effect transistor (NFET)) and a P-channel MISFET (hereinafter referred to as a PFET) are provided on a substrate to be adjacent to each other with a STI region as an isolation region interposed therebetween, a reduction in the threshold voltage of each of parasitic transistors formed in the vicinities of the edge portions of the STI region in the NFET and the PFET.

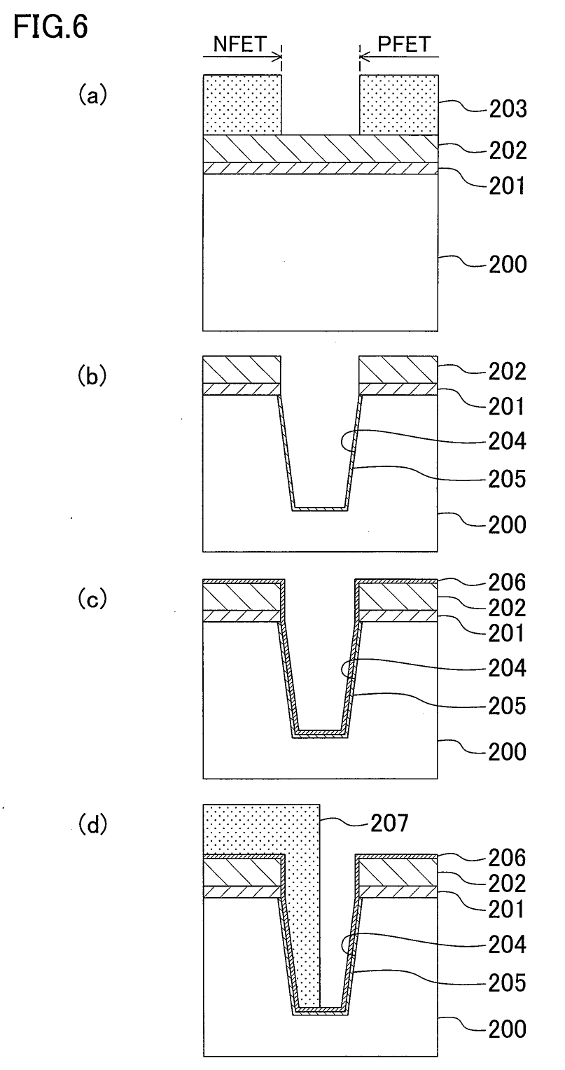

FIG. 5 shows a plan configuration of the semiconductor device according to the second illustrative example embodiment. FIGS. 6A-6D, 7A-7D, 8A-8C, 9A, and 9B are cross-sectional views illustrating the method for fabricating the semiconductor device according to the second illustrative example embodiment in the order of process steps, which specifically show cross sections each corresponding to the line IXb-IXb of FIG. 5 described above in the order of process steps. Note that, as shown in FIG. 5, parasitic transistors are assumed to be present in parasitic transistor formation regions 5A and 5B in the vicinities of the edges of a silicon dioxide film 210 serving as a STI (isolation insulating film) defining an NFET formation region and a PFET formation region in which the NFET and the PFET each including a source region S, a drain region D, and a gate electrode 217 are formed respectively.

First, as shown in FIG. 6A, a silicon dioxide film 201 having a thickness of, e.g., 10 nm is formed on a semiconductor substrate (hereinafter referred to as the “substrate”) 200 made of, e.g., silicon. Then, a silicon nitride film 202 having a thickness of, e.g., 70 nm is formed on the silicon dioxide film 201. Subsequently, a resist film is deposited on the silicon nitride film 202, and then a resist pattern 203 having an opening exposing the silicon nitride film 202 is formed using photolithographic and etching techniques.

Next, as shown in FIG. 6B, the silicon nitride film 202, the silicon dioxide film 201, and the substrate 200 are etched using the resist pattern 203 as a mask. As a result, a trench 204 having a depth of 300 nm is formed in the substrate 200. Thereafter, the resist pattern 203 is removed. Subsequently, by oxidizing the substrate 200, an underlying insulating film 205 made of a silicon dioxide film having a thickness of, e.g., 2 nm is formed over the sidewall portions and bottom portion of the trench 204. Here, an example has been described where the underlying insulating film 205 is a silicon dioxide film. However, the underlying insulating film 205 may also be made of, e.g., a silicon oxynitride film. Also, the thickness of the underlying insulating film 205 is not limited to 2 nm. The same effects as described later are obtainable as long as the thickness of the underlying insulating film 205 is in a range of about 0.5 to 15 nm.

Next, as shown in FIG. 6C, a protective film 206 made of an aluminum oxide film having a thickness of, e.g., 1 nm is deposited over the upper surface and side surfaces of the silicon nitride film 202, on the side surfaces of the silicon dioxide film 201, and on the underlying insulating film 205 using, e.g., an atomic layer deposition (ALD) process. Aluminum in the protective film 206 is introduced into the portion of a high-dielectric-constant gate insulating film made of a high-dielectric-constant material described later which becomes the parasitic transistor in the NFET, and operates to increase the threshold voltage of the parasitic transistor in the NFET. Here, as the protective film 206, a film containing a metal capable of increasing the threshold voltage of the parasitic transistor in the NFET, and having an etching rate lower than that of the isolation insulating film may be used appropriately. Instead of the aluminum oxide film, an aluminum film may also be used as the protective film 206. The description has been given to the case where the thickness of the protective film 206 is 1 nm, but it is not limited to the value. The thickness of the protective film 206 can be adjusted depending on a threshold voltage reduction in the parasitic transistor. That is, in the case where the threshold voltage reduction is assumed to decrease, the film thickness may be reduced (to, e.g., 0.5 nm) appropriately. On the other hand, in the case where the threshold voltage reduction is assumed to increase, the film thickness may be increased (to, e.g., 2 nm) appropriately.

Next, as shown in FIG. 6D, a resist film is deposited on the protective film 206, and then formed into a resist pattern 207 covering the NFET formation region, and having an opening over the PFET formation region using photolithographic and etching techniques.

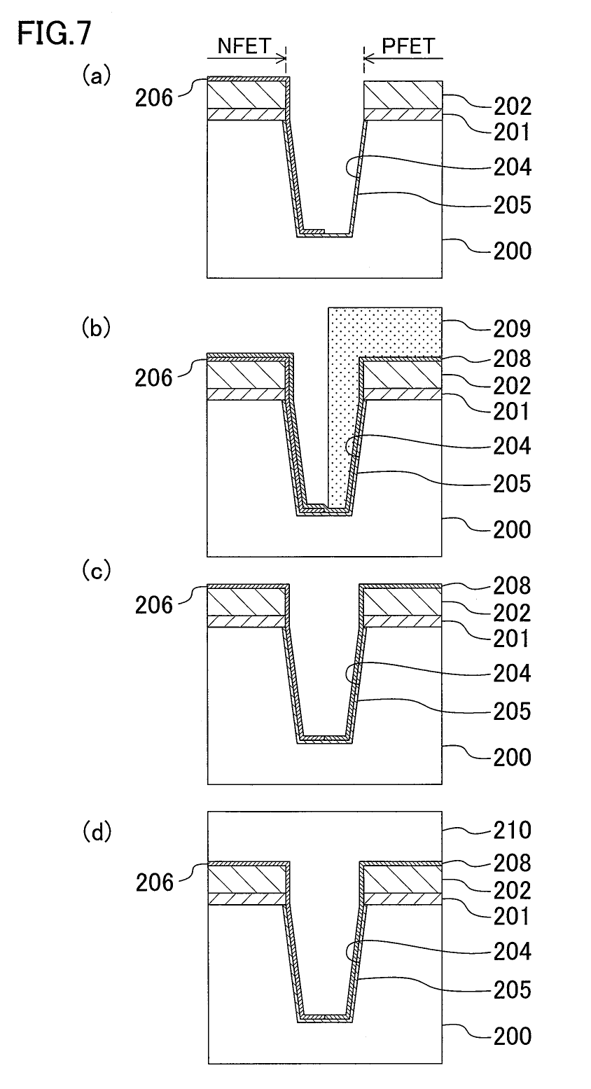

Next, as shown in FIG. 7A, the portion of the protective film 206 located in the PFET formation region is removed by etching using the resist pattern 207 as a mask, and using an alkaline solution of tetramethylammonium hydroxide (TMAH) or the like. Thereafter, the resist pattern 207 is removed.

Next, as shown in FIG. 7B, a protective film 208 made of a lanthanum oxide film having a thickness of, e.g., 1 nm is deposited on the portion of the protective film 206 located in the NFET formation region, on the portion of the underlying insulating film 205 located in the PFET formation region, on the side surface of the silicon dioxide film 201 in the PFET formation region, and over the upper surface and side surfaces of the silicon nitride film 202 in the PFET formation region using, e.g., an ALD process. Lanthanum in the protective film 208 is introduced into the portion of a high-dielectric-constant gate insulating film (gate insulating film 216) made of a high-dielectric-constant material described later which becomes the parasitic transistor in the PFET, and operates to increase the threshold voltage of the parasitic transistor in the PFET. Here, as the protective film 208, a film containing a metal capable of increasing the threshold voltage of the parasitic transistor in the PFET, and having an etching rate lower than that of the isolation insulating film may be used appropriately. For example, a film made of any one of lanthanum (La), dysprosium (Dy), scandium (Sc), erbium (Er), and strontium (Sr) or an oxide film of any one thereof can be used. The description has been given to the case where the thickness of the protective film 208 is 1 nm, but it is not limited to the value. The thickness of the protective film 208 can be adjusted depending on a threshold voltage reduction in the parasitic transistor. That is, in the case where the threshold voltage reduction is assumed to decrease, the thickness of the protective film 208 may be reduced (to, e.g., 0.5 nm) appropriately. On the other hand, in the case where the threshold voltage reduction is assumed to increase, the thickness of the protective film 208 may be increased (to, e.g., 2 nm) appropriately. Subsequently, a resist film is deposited on the protective film 208, and then formed into a resist pattern 209 covering the PFET formation region, and having an opening over the NFET formation region using photolithographic and etching techniques.

Next, as shown in FIG. 7C, the portion of the protective film 208 located in the NFET formation region is removed by etching using the resist pattern 209 as a mask, and using a chemical solution of, e.g., a hydrochloric acid or the like. Thereafter, the resist pattern 209 is removed.

Next, as shown in FIG. 7D, the silicon dioxide film 210 having a thickness of, e.g., 500 nm is formed over the entire surface of the substrate 200 so as to bury the inside of the trench 204 using, e.g., a plasma chemical vapor deposition (CVD) process or a thermal CVD process. In this manner, electrical isolation using the silicon dioxide film 210 serving as the isolation insulating film of the STI region is achieved.

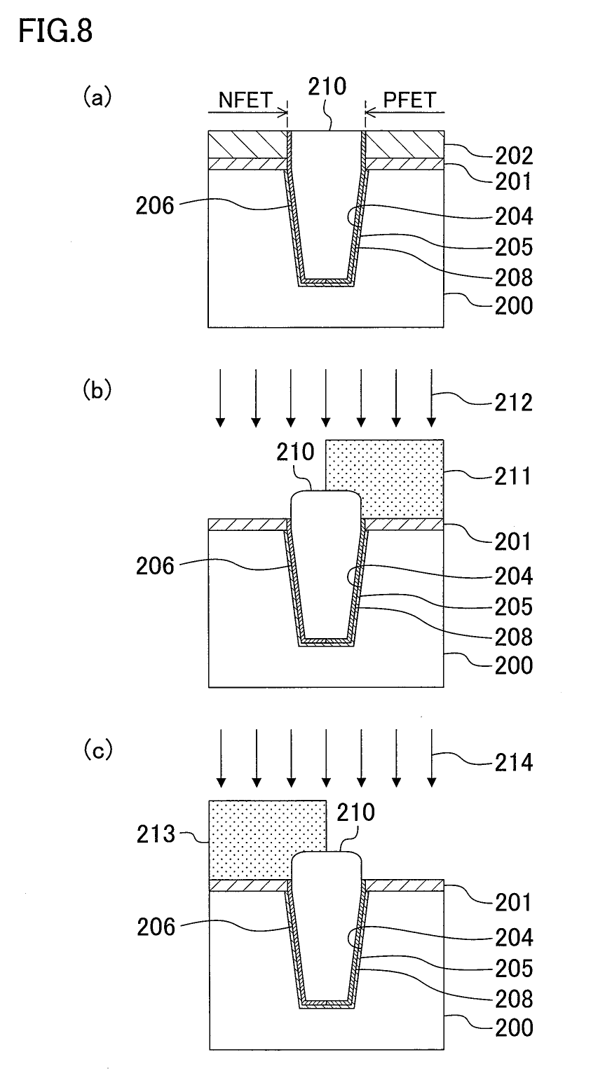

Next, as shown in FIG. 8A, the portion of the silicon dioxide film 210 located over the silicon nitride film 202 and the portions of the protective films 206 and 208 located over the silicon nitride film 202 are removed by polishing to provide a planarized surface.

Next, as shown in FIG. 8B, the portion of the silicon nitride film 202 located over the silicon dioxide film 201 and the portions of the protective films 206 and 208 located over the silicon dioxide film 201 are removed by etching using a chemical solution of, e.g., a phosphoric acid or the like. Subsequently, a resist pattern 211 covering the PFET formation region, and having an opening over the NFET formation region is formed, and then impurity implantation 212 is performed to the substrate 200 using the resist pattern 211 as a mask. Thereafter, the resist pattern 211 is removed. Here, a P-type impurity such as, e.g., boron or indium is used as an impurity used for the impurity implantation 212 to form a well and adjust the threshold voltage of a channel region.

Next, as shown in FIG. 8C, a resist pattern 213 covering the NFET formation region, and having an opening over the PFET formation region is formed, and then impurity implantation 214 is performed to the substrate 200 using the resist pattern 213 as a mask. Thereafter, the resist pattern 213 is removed. Here, an N-type impurity such as, e.g., arsenic or phosphorus is used as an impurity used for the impurity implantation 214 to form a well and adjust the threshold voltage of a channel region.

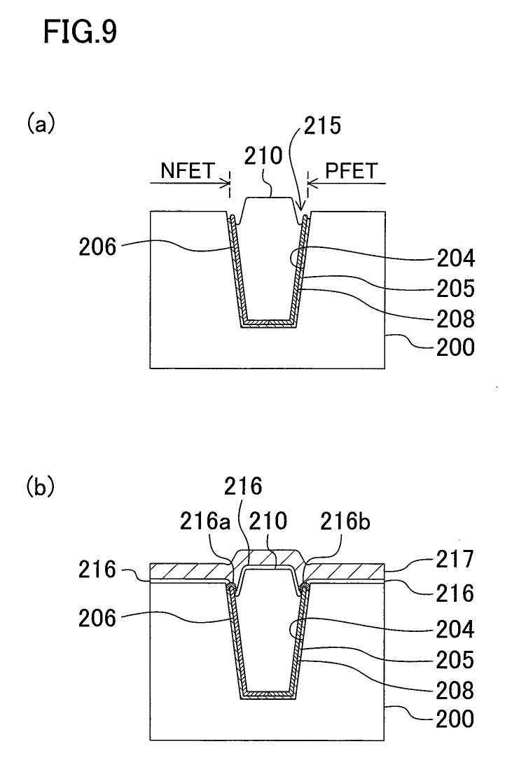

Next, as shown in FIG. 9A, annealing for activating the impurities implanted in the substrate 200 is performed. Subsequently, the silicon dioxide film 201 is removed by etching using a chemical solution of, e.g., a hydrofluoric acid or the like. At this time, the upper portions of the respective portions of the underlying insulating film 205 and the protective films 206 and 208 located at the sidewall portions of the trench 204 and a part of the silicon dioxide film 210 buried in the trench 204 are removed due to the chemical solution that has reached there. Note that the amount of the silicon dioxide film 210 removed here is larger than that of each of the protective films 206 and 208 removed. As a result, divots 215 are formed at the upper portions of the sidewall portions of the trench 204 and between the protective films 206 and 208 and the silicon dioxide film 210.

Next, as shown in FIG. 9B, by, e.g., an ALD process, the gate insulating film (high-dielectric-constant gate insulating film) 216 made of a hafnium oxide (HfO₂) film which is a high-dielectric-constant material having a thickness of, e.g., 2 nm is formed on the upper portion of the substrate 200, on the upper portions of the respective portions of the underlying insulating film 205 and the protective films 206 and 208 located at the sidewall portions of the trench 204, and on the silicon dioxide film 210. Subsequently, the gate electrode 217 made of a titanium nitride (TiN) film having a thickness of, e.g., 100 nm is formed on the gate insulating film 216. At this time, the lowermost bottom surfaces of the portions (portions located at the upper portions of the sidewall portions of the trench 204) of the gate electrode 217 buried in the divots 215 over the gate insulating film 216 are at positions (height positions) lower than the positions (height positions) of the respective upper surfaces of the element formation regions where the NFET and the PFET are to be formed.

Here, the description has been given to the case where the gate insulating film 216 is a HfO₂ film, and the gate electrode 217 is a TiN film. However, the gate insulating film 216 and the gate electrode 217 are not limited to these thicknesses and materials. For example, as the gate insulating film 216, there may also be used a high-dielectric-constant material such as a hafnium oxide (HfO₂) film, a hafnium silicon oxide (HfSiO) film, a hafnium silicon oxynitride (HfSiON) film, a zirconium dioxide (ZrO₂) film, or a hafnium-zirconium oxide (HfZrO) film. As the gate electrode 217, there may also be used a single-layer film of any one of the titanium nitride (TiN) film mentioned above, a tantalum nitride (TaN) film, a tantalum carbide (TaC) film, a tantalum carbonitride (TaCN) film, and the like, a laminated film of any two or more thereof, or a laminated film of any one thereof and a polysilicon film formed thereon. Further, by introducing lanthanum (La), dysprosium (Dy), scandium (Sc), erbium (Er), or strontium (Sr) into the portion of the gate insulating film 216 located over the substrate 200 in the NFET formation region, it is possible to inhibit an increase in the threshold voltage of the NFET in the upper portion of the substrate 200 due to the gate insulating film 216 made of the high-dielectric-constant material mentioned above. Likewise, by introducing Al into the portion of the gate insulating film 216 located over the substrate 200 in the PFET formation region, it is possible to inhibit an increase in the threshold voltage of the PFET in the upper portion of the substrate 200 due to the gate insulating film 216 made of the high-dielectric-constant material mentioned above.

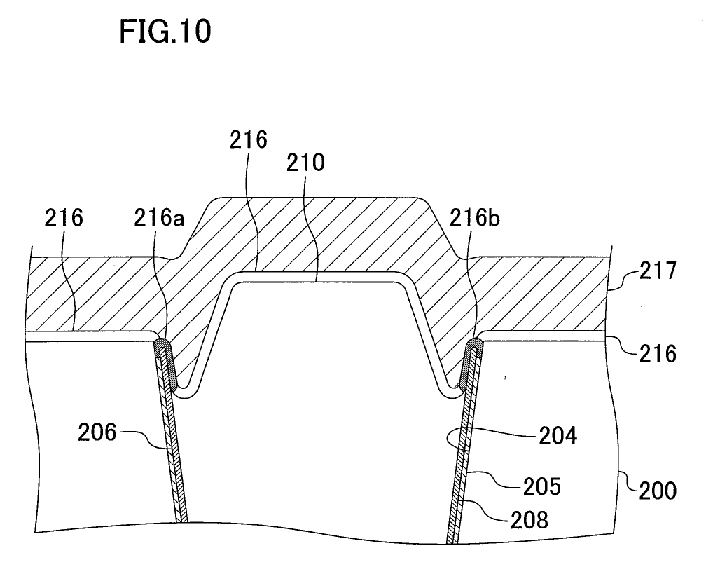

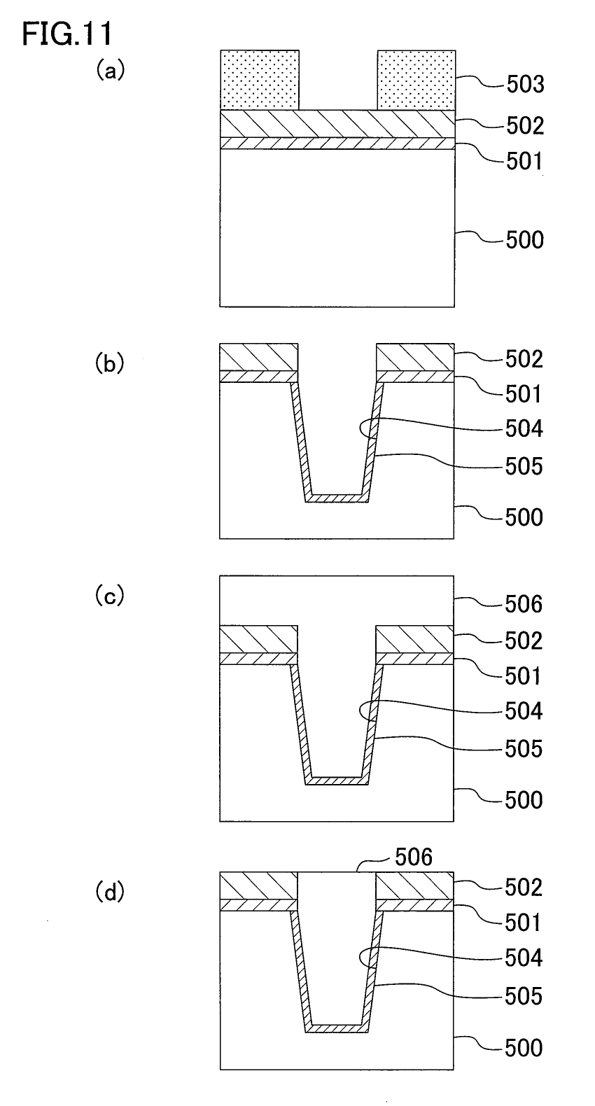

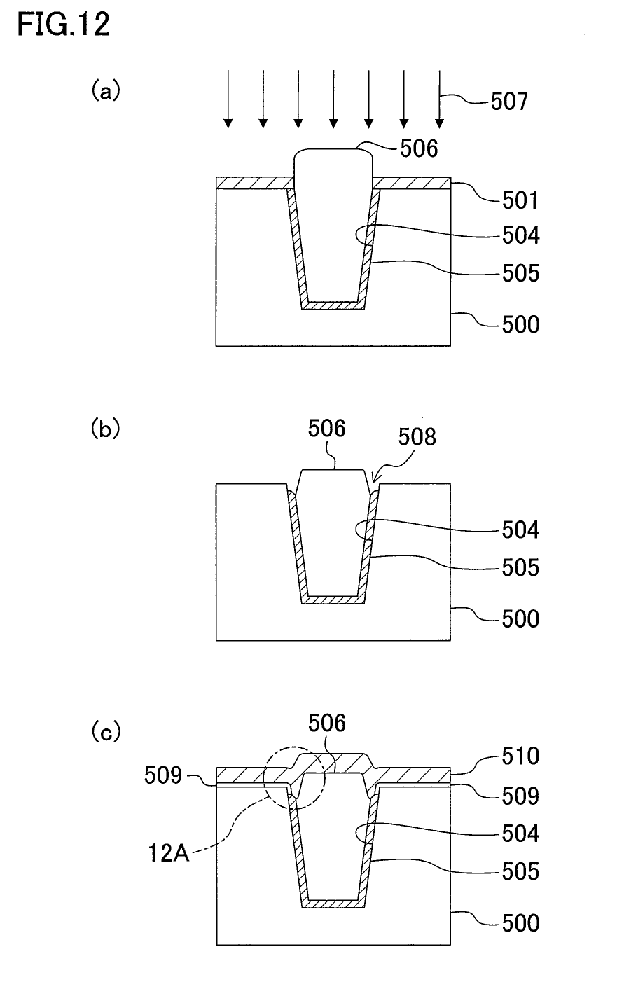

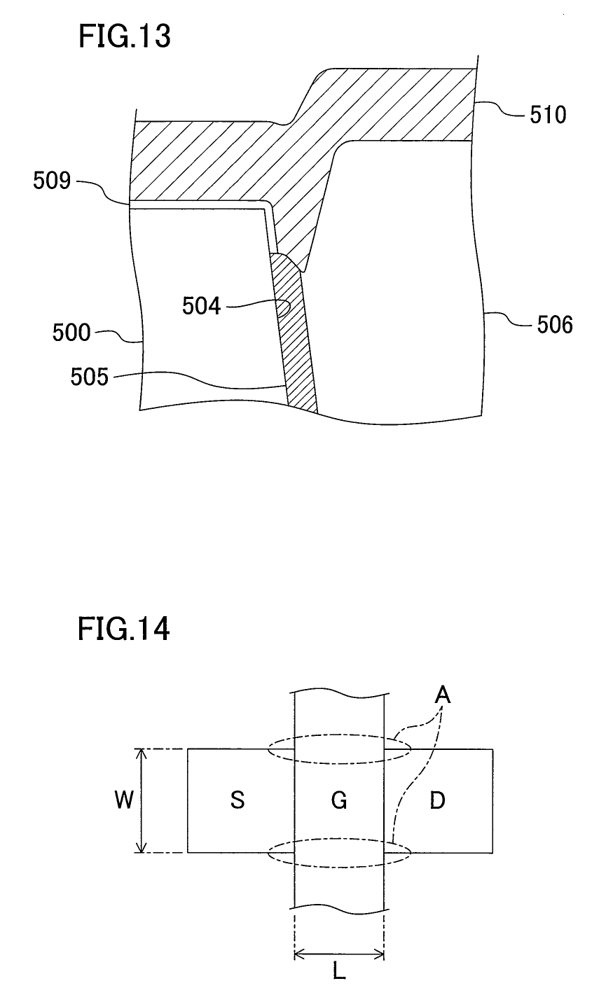

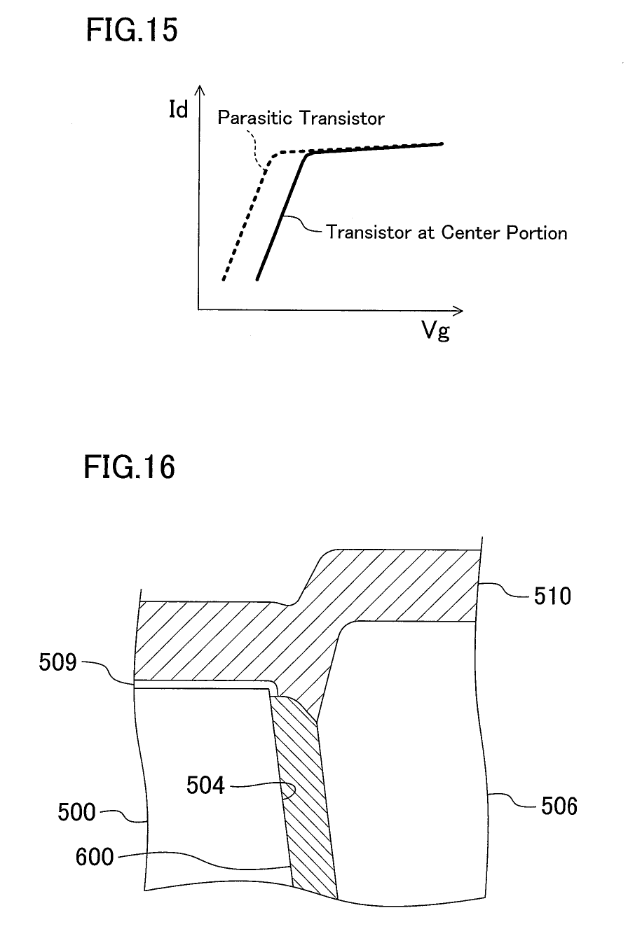

FIG. 10 is a cross-sectional view showing the structure of the semiconductor device according to the second illustrative example embodiment fabricated in the manner described above, which is an enlarged cross-sectional view of the principal portion of FIG. 9B described above.

As shown in FIG. 10, in the NFET formation region and in the vicinity of the edge of the silicon dioxide film 210 serving as the isolation insulating film of the STI region (see FIG. 5) defining the NFET formation region and the PFET formation region of the substrate 200, the protective film 206 made of, e.g., an aluminum oxide film is formed between the portion of the underlying insulating film 205 formed at the sidewall portion of the trench 204 and the gate insulating film 216. An aluminum-containing gate insulating film 216a for increasing the threshold voltage of the parasitic transistor in the NFET is formed in the portion of the gate insulating film 216 located at the upper portion of the sidewall portion of the trench 204 in contact with the protective film 206. On the other hand, in the PFET formation region and in the vicinity of the edge of the silicon dioxide film 210 serving as the isolation insulating film of the STI region, the protective film 208 made of, e.g., a lanthanum oxide film is formed between the portion of the underlying insulating film 205 formed at the sidewall portion of the trench 204 and the gate insulating film 216. A lanthanum-containing gate insulating films 216b for increasing the threshold voltage of the parasitic transistor in the PFET is formed in the portion of the gate insulating film 216 located at the upper portion of the sidewall portion of the trench 204 in contact with the protective film 208. The aluminum-containing gate insulating film 216a and the lanthanum-containing gate insulating film 216b are formed through the introduction of aluminum in the protective film 206 and lanthanum in the protective film 208 into the gate insulating film 216 by a thermal process after the formation of the gate insulating film 216. Accordingly, aluminum is not introduced into the portion of the gate insulating film 216 interposed between the gate electrode 217 and the upper surface of the NFET element formation region, especially at least the portion thereof spaced apart from the trench 204. Likewise, lanthanum is not introduced into the portion of the gate insulating film 216 interposed between the gate electrode 217 and the upper surface of the PFET element formation region, especially at least the portion thereof spaced apart from the trench 204.

Since the aluminum-containing gate insulating film 216a is thus formed due to the presence of the protective film 206 in the vicinity of the edge of the STI region in the NFET formation region, even when the divot 215 is formed in the vicinity of the edge portion of the STI region, and a parasitic transistor is formed in the NFET, it is possible to inhibit a reduction in the threshold voltage of the parasitic transistor. Likewise, since the lanthanum-containing gate insulating film 216b is formed due to the presence of the protective film 208 in the vicinity of the edge of the STI region in the PFET formation region, even when the divot 215 is formed in the vicinity of the edge portion of the STI region, and a parasitic transistor is formed in the PFET, it is possible to inhibit a reduction in the threshold voltage of the parasitic transistor. In the case of the structure of the semiconductor device according to the second illustrative example embodiment, by providing the protective films 206 and 208, the threshold voltage of each of the parasitic transistors in the parasitic transistor formation regions 5A and 5B can be improved by about 200 mV. This allows a reduction in the characteristic variations of each of the transistors. In addition, as described above, the thickness of the underlying insulating film 205 may fall appropriately within a range of about 0.5 to 15 nm, and the thicknesses of the protective films 206 and 208 may fall appropriately within a range of about 0.5 to 2 nm. Therefore, even when the miniaturization of the transistors advances, the structure according to the second illustrative example embodiment is applicable thereto.

In the structure of the semiconductor device and the method for fabricating the same according to the second illustrative example embodiment described above, the structure is shown in which the protective film 206 is interposed between the underlying insulating film 205 and the aluminum-containing gate insulating film 216a or the protective film 208 is interposed between the underlying insulating film 205 and the lanthanum-containing gate insulating film 216b in the vicinity of the edge of the STI region. However, the boundaries of the protective films 206 and 208 need not be distinct. For example, even in a structure in which the underlying insulating film 205 and the aluminum-containing gate insulating film 216a are in contact with each other with an interface layer having a high aluminum concentration interposed therebetween or the underlying insulating film 205 and the lanthanum-containing gate insulating film 216b are in contact with each other with an interface layer having a high lanthanum concentration interposed therebetween, the same effects as described above are obtainable.

In the method for fabricating the semiconductor device according to the second illustrative example embodiment described above, the description has been given to the case where the protective film 206 made of, e.g., an aluminum oxide film is formed in the NFET formation region (see FIG. 7A), and then the protective film 208 made of, e.g., a lanthanum oxide film is formed in the PFET formation region (see FIG. 7C). However, it is also possible to reverse the order in which the protective films 206 and 208 are formed. That is, it is also possible to form the protective film 208 made of, e.g., a lanthanum oxide film in the PFET formation region, and then form the protective film 206 made of, e.g., an aluminum oxide film in the NFET formation region.

In the case of forming the gate insulating film 216 by a CVD process, the gate insulating film 216 tends to be thinner in the divots 215 in the three-dimensional structure due to a reduced deposition speed. This causes concern about a reduction in the threshold voltage of the parasitic transistor due to the thinner gate insulating film 216. However, in the structure of the semiconductor device and the method for fabricating the same according to the second illustrative example embodiment described above, the protective films 206 and 208 are provided, and therefore a reduction in the threshold voltage of each of the parasitic transistors can be inhibited.

The present disclosure is useful for, e.g., a transistor having a high-dielectric-constant gate insulating film.

What is claimed is:

1. A semiconductor device, comprising:
a first MIS transistor formed in a first element formation region of a semiconductor substrate;
an isolation region formed in a trench provided in the semiconductor substrate to define the first element formation region;
a first high-dielectric-constant gate insulating film formed over the first element formation region and the isolation region; and
a first gate electrode formed on the first high-dielectric-constant gate insulating film, wherein
a first portion of the first high-dielectric-constant gate insulating film formed between a portion of the first gate electrode located in the trench and a side surface of the first element formation region contains a first metal, and
a second portion of the first high-dielectric-constant gate insulating film formed between the first gate electrode and an upper surface of the first element formation region does not contain the first metal.

2. The semiconductor device of claim 1, wherein a lowermost surface of a region of the first gate electrode formed on the first portion of the first high-dielectric-constant gate insulating film is at a position lower than a position of the upper surface of the first element formation region.

3. The semiconductor device of claim 1, wherein at least a portion of the second portion of the first high-dielectric-constant gate insulating film spaced apart from the trench does not contain the first metal.

4. The semiconductor device of claim 1, wherein the isolation region has:
an isolation insulating film formed in the trench;
a first underlying insulating film formed between the first element formation region and the isolation insulating film and at a sidewall portion of the trench; and
a first protective film formed between the isolation insulating film and the first underlying insulating film, and containing the first metal.

5. The semiconductor device of claim 4, wherein the first gate electrode is formed on the side surface of the first element formation region with the first underlying insulating film, the first protective film, and the first portion of the first high-dielectric-constant gate insulating film interposed therebetween.

6. The semiconductor device of claim 4, wherein the first underlying insulating film is made of a silicon dioxide film or a silicon oxynitride film.

7. The semiconductor device of claim 4, wherein
the first MIS transistor is an N-channel MIS transistor, and
the first protective film is made of an aluminum film or an aluminum oxide film.

8. The semiconductor device of claim 1, wherein
the first MIS transistor is an N-channel MIS transistor, and
the first metal is aluminum.

9. The semiconductor device of claim 1, wherein
the first MIS transistor is an N-channel MIS transistor, and
the second portion of the first high-dielectric-constant gate insulating film contains any one selected from the group consisting of lanthanum, dysprosium, scandium, erbium, and strontium.

10. The semiconductor device of claim 4, wherein
the first MIS transistor is a P-channel MIS transistor, and
the first protective film is made of a film made of any one selected from the group consisting of lanthanum, dysprosium, scandium, erbium, and strontium or an oxide film of any one selected therefrom.

11. The semiconductor device of claim 1, wherein
the first MIS transistor is a P-channel MIS transistor, and
the first metal is lanthanum, dysprosium, scandium, erbium, or strontium.

12. The semiconductor device of claim 1, wherein
the first MIS transistor is a P-channel MIS transistor, and
the second portion of the first high-dielectric-constant gate insulating film contains aluminum.

13. The semiconductor device of claim 1, wherein
the first high-dielectric-constant gate insulating film is made of a hafnium oxide film, a hafnium silicon oxide film, a hafnium silicon oxynitride film, a zirconium dioxide film, or a hafnium-zirconium oxide film.

14. The semiconductor device of claim 1, wherein
the first gate electrode has a film of at least one of titanium nitride, tantalum nitride, tantalum carbide, and tantalum carbonitride.

15. The semiconductor device of claim 1, wherein
the isolation region defines the first element formation region, and a second element formation region of the semiconductor substrate where a second MIS transistor is formed,
the semiconductor device further comprising:
a second high-dielectric-constant gate insulating film formed over the second element formation region and the isolation region; and
a second gate electrode formed on the second high-dielectric-constant gate insulating film, wherein
a first portion of the second high-dielectric-constant gate insulating film formed between a portion of the second gate electrode located in the trench and a side surface of the second element formation region contains a second metal different from the first metal, and a second portion of the second high-dielectric-constant gate insulating film formed between the second gate electrode and an upper surface of the second element formation region does not contain the second metal.

16. The semiconductor device of claim 15, wherein the isolation region has:
an isolation insulating film formed in the trench;
a first underlying insulating film formed between the first element formation region and the isolation insulating film and at a sidewall portion of the trench;
a first protective film formed between the isolation insulating film and the first underlying insulating film, and containing the first metal;
a second underlying insulating film formed between the second element formation region and the isolation insulating film and at a sidewall portion of the trench; and
a second protective film formed between the isolation insulating film and the second underlying insulating film, and containing the second metal.

17. The semiconductor device of claim 16, wherein
the first MIS transistor is an N-channel MIS transistor,
the second MIS transistor is a P-channel MIS transistor,
the first protective film is made of an aluminum film or an aluminum oxide film, and
the second protective film is made of a film made of any one selected from the group consisting of lanthanum, dysprosium, scandium, erbium, and strontium or an oxide film of any one selected therefrom.

18. The semiconductor device of claim 15, wherein
the first MIS transistor is an N-channel MIS transistor,
the second MIS transistor is a P-channel MIS transistor,
the first metal is aluminum, and
the second metal is lanthanum, dysprosium, scandium, erbium, or strontium.

19. A method for fabricating a semiconductor device comprising a first MIS transistor formed in a first element formation region of a semiconductor substrate, the method comprising the steps of:
(a) forming a trench defining the first element formation region in the semiconductor substrate, and then forming an isolation region in the trench;
(b) forming a first high-dielectric-constant gate insulating film over the first element formation region and the isolation region;
(c) forming a first gate electrode on the first high-dielectric-constant gate insulating film; and
(d) introducing a first metal into a first portion of the first high-dielectric-constant gate insulating film formed between a portion of the first gate electrode located in the trench and a side surface of the first element formation region, wherein,
in the step (d), the first metal is not introduced into a second portion of the first-high-dielectric-constant gate insulating film formed between the first gate electrode and an upper surface of the first element formation region.

20. The method of claim 19, wherein the step (a) has the steps of:
(a1) forming the trench in the semiconductor substrate;
(a2) successively forming a first underlying insulating film and a first protective film containing the first metal at a sidewall portion of the trench in the first element formation region; and,
(a3) after the step (a2), forming an isolation insulating film to fill the inside of the trench therewith, wherein
the step (d) includes the step of introducing the first metal contained in the first protective film into the first high-dielectric-constant gate insulating film.
